(19) United States
(12) Patent Application Publication
(10) Pub. No.: US 2025/0358494 A1
(43) Pub. Date: Nov. 20, 2025

(54) IMAGING APPARATUS AND IMAGING ELEMENT

(71) Applicant: FUJIFILM Corporation, Tokyo (JP)

(72) Inventors: Yota AKASHI, Saitama-shi (JP); Kazuya ODA, Saitama-shi (JP); Tomoyuki KAWAI, Saitama-shi (JP); Yoshinori FURUTA, Saitama-shi (JP); Makoto KOBAYASHI, Saitama-shi (JP); Seiji TANAKA, Saitama-shi (JP)

(73) Assignee: FUJIFILM Corporation, Tokyo (JP)

(21) Appl. No.: 19/284,617

(22) Filed: Jul. 29, 2025

Related U.S. Application Data
(63) Continuation of application No. PCT/JP2023/045786, filed on Dec. 20, 2023.

(30) Foreign Application Priority Data
Jan. 31, 2023 (JP) 2023-013450

(51) Int. Cl. H04N 23/12; H04N 23/67; H04N 23/69; H04N 23/84

(52) U.S. Cl. CPC H04N 23/12; H04N 23/67; H04N 23/69; H04N 23/84

(57) ABSTRACT

An imaging apparatus includes: an imaging element that images a subject through an imaging optical system, the imaging element includes plural pixels corresponding respectively to plural wavelength ranges, the imaging element includes a first pixel in which a light reducing member having plural openings is disposed and a second pixel in which the light reducing member is not provided, and the first pixel corresponds to a first wavelength range among the plural wavelength ranges.

### CROSS REFERENCE TO RELATED APPLICATION

This is a continuation of International Application No. PCT/JP2023/045786 filed on Dec. 20, 2023, and claims priority from Japanese Patent Application No. 2023-013450 filed on Jan. 31, 2023, the entire disclosures of which are incorporated herein by reference.

### BACKGROUND OF THE INVENTION

### 1. Field of the Invention

The present invention relates to an imaging apparatus and an imaging element.

### 2. Description of the Related Art

JP2022-099612A discloses a solid-state imaging element comprising a wafer substrate having a plurality of photoelectric conversion elements, an organic film formed on the wafer substrate with a resin having a carboxylic acid in a skeleton as a main component, a light shielding layer formed on the organic film with a titanium-based black material as a main component and having a plurality of openings, and a plurality of microlenses disposed on the openings or in the openings.

JP2012-019360A discloses a solid-state imaging device comprising a plurality of pixels each having a photoelectric conversion element, and a light shielding layer covering the photoelectric conversion element, in which the light shielding layer has, in the photoelectric conversion element of each of the plurality of pixels, a light shielding unit for blocking a part of incident light on the photoelectric conversion element and an opening portion for allowing transmission of a remaining part of the incident light, the plurality of pixels include at least two types of pixels having different areas of the photoelectric conversion elements in a plan view, and the larger the area of the pixel in the plan view of the photoelectric conversion element, the larger the area of the light shielding unit.

JP2009-146957A discloses a solid-state imaging device comprising a semiconductor substrate in which a photoelectric conversion element is formed on a main surface, and which comprises a light-receiving pixel region, a boundary pixel region, and a light shielding pixel region, an interlayer insulating film formed on the semiconductor substrate, a wiring layer formed on the interlayer insulating film, a first in-layer lens formed on the interlayer insulating film in the light-receiving pixel region, a first incident light restriction film formed on the interlayer insulating film in the boundary pixel region, and a light shielding film formed on the interlayer insulating film in the light shielding pixel region, in which the boundary pixel region is formed between the light-receiving pixel region and the light shielding pixel region.

JP2016-052041A discloses a solid-state imaging element comprising a pixel unit in which one of microlenses is formed for a plurality of pixels such that a boundary of the microlens coincides with a boundary of the pixel, and a correction circuit that corrects a sensitivity difference between the pixels in the pixel unit based on a correction coefficient.

JP1993-86670B (JP-H5-86670B) discloses that a light shielding film having a large number of openings in a mesh shape is used as restricting means for partially restricting incident light for each pixel of an imaging element.

### SUMMARY OF THE INVENTION

An imaging apparatus and an imaging element according to one embodiment of the technology of the present disclosure are as follows.

(1)

An imaging apparatus comprising:
an imaging element that images a subject through an imaging optical system,
in which the imaging element includes a plurality of pixels corresponding respectively to a plurality of wavelength ranges,
the imaging element includes a first pixel in which a light reducing member having a plurality of openings is disposed and a second pixel in which the light reducing member is not provided, and
the first pixel corresponds to a first wavelength range among the plurality of wavelength ranges.
   (2)

The imaging apparatus according to (1),
the second pixel includes a pixel corresponding to the first wavelength range.
   (3)

The imaging apparatus according to (2),
in which the first wavelength range is a wavelength range that contributes most to obtaining a brightness signal.
   (4)

The imaging apparatus according to (3),
in which the first pixel includes a plurality of pixels, the second pixel includes a plurality of pixels, the plurality of pixels included in the second pixel includes pixels respectively corresponding to each wavelength range other than the first wavelength range among the plurality of wavelength ranges, and all of the plurality of pixels included in the first pixel correspond to the first wavelength range.
   (5)

The imaging apparatus according to any one of (1) to (4), further comprising:
a processor,
in which the processor is configured to:
   perform processing, on output data of the first pixel, of correcting a sensitivity difference between the first pixel and the second pixel based on a position of the first pixel and information indicating a state of the imaging optical system.
      (6)

The imaging apparatus according to any one of (1) to (4), further comprising:
a processor,
in which the processor is configured to:
   perform processing, on output data of the first pixel, of correcting a variation in the output data of the first pixel in an imaging surface based on a position of the first pixel and information indicating a state of the imaging optical system.
      (7)

The imaging apparatus according to (5) or (6),
in which the information includes at least one of an F number (an aperture value), a focus lens position, or a zoom lens position.
   (8)

The imaging apparatus according to any one of (5) to (7), further comprising:
a memory,
in which correction data used in the processing is stored in the memory for each combination of the position of the first pixel and the information indicating the state of the imaging optical system.
   (9)

The imaging apparatus according to (8),
in which the correction data is stored in the memory for each type of the imaging optical system.
   (10)

The imaging apparatus according to (5) or (6),
in which the processor is configured to:
   estimate light amount distribution for each wavelength of light incident on the first pixel based on output data of the second pixel; and
   perform the processing on the output data of the first pixel based on the light amount distribution, the position of the first pixel, and the information.
      (11)

The imaging apparatus according to (10),
in which the information includes at least one of an F number (an aperture value), a focus lens position, or a zoom lens position.
   (12)

The imaging apparatus according to (10) or (11), further comprising:
a memory,
in which correction data used in the processing is stored in the memory for each combination of the light amount distribution, the position of the first pixel, and the information indicating the state of the imaging optical system.
   (13)

The imaging apparatus according to (12),
in which the correction data is stored in the memory for each type of the imaging optical system.
   (14)

The imaging apparatus according to any one of (1) to (3), further comprising:
a processor,
in which the imaging element has the first pixel corresponding to a second wavelength range among the plurality of wavelength ranges, and
the processor is configured to:
   perform processing, on output data of the first pixel, of correcting a sensitivity difference between the first pixel and the second pixel based on a position of the first pixel, information indicating a state of the imaging optical system, and a wavelength range corresponding to the first pixel.
      (15)

The imaging apparatus according to any one of (1) to (3), further comprising:
a processor,
in which the imaging element has the first pixel corresponding to a second wavelength range among the plurality of wavelength ranges, and
the processor is configured to:
   perform processing, on output data of the first pixel, of correcting a variation in the output data of the first pixel in an imaging surface based on a position of the first pixel, information indicating a state of the imaging optical system, and a wavelength range corresponding to the first pixel.
      (16)

The imaging apparatus according to any one of (1) to (4),
in which the first pixel includes a plurality of types in which dispositions of the plurality of openings are different from each other.
   (17)

The imaging apparatus according to (16), further comprising:
a processor,
in which the processor is configured to:
   correct output data of each of a plurality of the first pixels based on output data of the plurality of first pixels of different types.
      (18)

The imaging apparatus according to any one of (1) to (4), further comprising:
a processor,
in which the processor is configured to:
   perform color mixing correction on output data of the second pixel disposed adjacent to the first pixel based on a position of the first pixel and information indicating a state of the imaging optical system.
      (19)

The imaging apparatus according to (18),
in which the information includes at least one of an F number (an aperture value), a focus lens position, or a zoom lens position.
   (20)

An imaging element that images a subject through an imaging optical system, the imaging element comprising:
a plurality of pixels corresponding respectively to a plurality of wavelength ranges,
in which the plurality of pixels includes a first pixel in which a light reducing member having a plurality of openings is disposed and a second pixel in which the light reducing member is not provided, and
the first pixel corresponds to a first wavelength range among the plurality of wavelength ranges.

### BRIEF DESCRIPTION OF THE DRAWINGS

FIG. 1 is a diagram showing a schematic configuration of a digital camera 100 which is an embodiment of an imaging apparatus according to the present invention.

FIG. 2 is a schematic plan view showing a schematic configuration of an imaging element 5 shown in FIG. 1.

FIG. 3 is a schematic diagram showing a partially enlarged imaging surface 60 of the imaging element 5 shown in FIG. 2.

FIG. 4 is a diagram showing sensitivity characteristics of a high-sensitivity pixel 61GH and a low-sensitivity pixel 61GL.

FIG. 5 is a schematic cross-sectional view of a pixel 61R and the high-sensitivity pixel 61GH in a range A1 shown in FIG. 3.

FIG. 6 is a schematic cross-sectional view of a pixel 61B and the low-sensitivity pixel 61GL in a range A2 shown in FIG. 3.

FIG. 7 is a schematic plan view of a light reducing member 70 shown in FIG. 6 as viewed from a microlens ML side.

FIG. 8 is a schematic diagram for describing a change in a sensitivity difference between the high-sensitivity pixel 61GH and the low-sensitivity pixel 61GL depending on an F number (F value).

FIG. 9 is a schematic diagram for describing a change in a sensitivity difference between the high-sensitivity pixel 61GH and the low-sensitivity pixel 61GL depending on an image height.

FIG. 10 is a graph showing a change in output data of the low-sensitivity pixel 61GL and the high-sensitivity pixel 61GH depending on the image height.

FIG. 11 is a schematic diagram showing an example of a correction table stored in a memory.

FIG. 12 is a schematic diagram showing an example of a correction table stored in a memory.

FIG. 13 is a schematic diagram describing the magnitude of color mixing components for each pixel.

FIG. 14 is a diagram showing a modification example of a configuration of the low-sensitivity pixel 61GL in the imaging element 5, and is an enlarged plan view of a range A3 in FIG. 3.

FIG. 15 is a diagram showing an exterior of a smartphone 200.

FIG. 16 is a block diagram showing a configuration of the smartphone 200 shown in FIG. 15.

### DESCRIPTION OF THE PREFERRED EMBODIMENTS

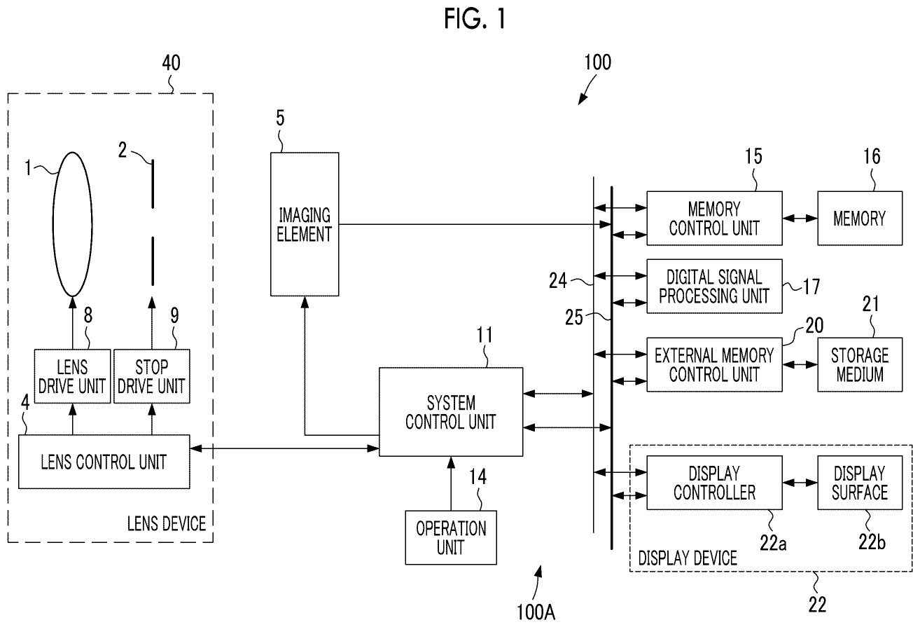

FIG. 1 is a diagram showing a schematic configuration of a digital camera 100 which is an embodiment of an imaging apparatus according to the present invention. The digital camera 100 shown in FIG. 1 comprises a lens device 40 including an imaging lens 1, a stop 2, a lens drive unit 8 that drives the imaging lens 1, a stop drive unit 9 that drives the stop 2, and a lens control unit 4 that controls the lens drive unit 8 and the stop drive unit 9, and a body part 100A.

The body part 100A comprises an imaging element 5, a system control unit 11 that manages and controls the entire electric control system of the digital camera 100, an operation unit 14, a display device 22, a memory 16 including a random access memory (RAM), a read only memory (ROM), and the like, and a memory control unit 15 that controls data storage in the memory 16 and data readout from the memory 16, a digital signal processing unit 17, and an external memory control unit 20 that controls data storage in a storage medium 21 and data readout from the storage medium 21.

The lens device 40 may be attachable to and detachable from the body part 100A or may be integrated with the body part 100A. The imaging lens 1 includes at least one of a focus lens or a zoom lens that is movable in an optical axis direction.

The focus lens is a lens for adjusting a focal point of an imaging optical system including the imaging lens 1 and the stop 2, and is composed of a single lens or of a plurality of lenses. By moving the focus lens in the optical axis direction, a position of a principal point of the focus lens (hereinafter, also referred to as a focus lens position) changes along the optical axis direction, and a focal position on a subject side is changed. A liquid lens of which a position of a principal point in the optical axis direction can be changed by electric control may be used as the focus lens.

The zoom lens is a lens for changing a focal length of the imaging optical system including the imaging lens 1 and the stop 2, and is composed of a single lens or of a plurality of lenses. By moving the zoom lens in the optical axis direction, the zoom magnification is changed.

The lens control unit 4 of the lens device 40 changes the focus lens position or the zoom lens position by controlling the lens drive unit 8 based on a lens drive signal transmitted from the system control unit 11. The lens control unit 4 of the lens device 40 changes an amount of opening (F value) of the stop 2 by controlling the stop drive unit 9 based on a driving control signal transmitted from the system control unit 11.

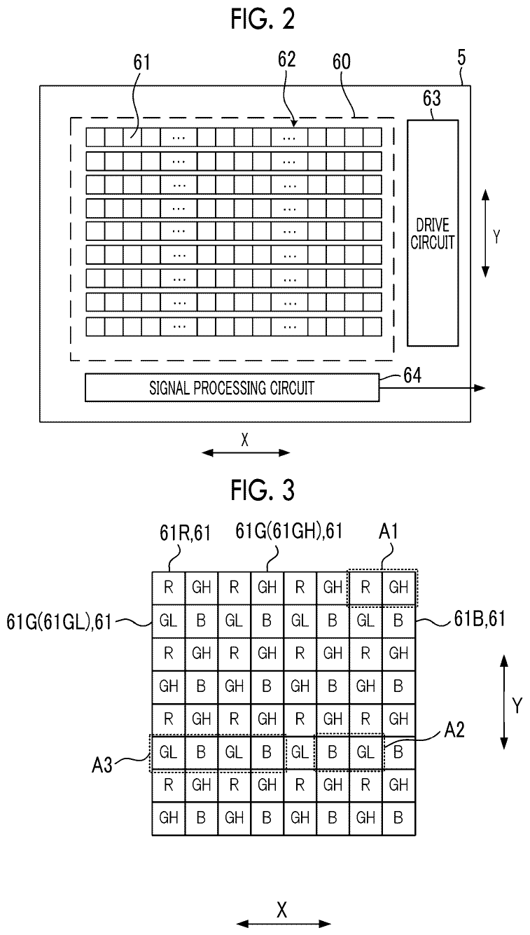

The imaging element 5 images a subject through the imaging optical system including the imaging lens 1 and the stop 2. The imaging element 5 includes an imaging surface 60 (refer to FIG. 2) on which a plurality of pixels are two-dimensionally arranged, converts a subject image formed on the imaging surface 60 by the imaging optical system into image signals by the plurality of pixels, and outputs the image signals.

For example, a complementary metal-oxide semiconductor (CMOS) image sensor or a charge coupled device (CCD) image sensor is used as the imaging element 5. Hereinafter, an example in which the imaging element 5 is a CMOS image sensor will be described.

The system control unit 11 manages and controls the entire digital camera 100 and has a hardware structure corresponding to various processors that perform processing by executing programs. The programs executed by the system control unit 11 are stored in the ROM (non-transitory storage medium) of the memory 16.

Examples of the various processors include a central processing unit (CPU) that is a general-purpose processor performing various types of processing by executing a program, a programmable logic device (PLD) such as a field programmable gate array (FPGA) that is a processor of which a circuit configuration can be changed after manufacture, or a dedicated electric circuit such as an application specific integrated circuit (ASIC) that is a processor having a circuit configuration dedicatedly designed to execute specific processing. More specifically, a structure of these various processors is an electric circuit in which circuit elements such as semiconductor elements are combined.

The system control unit 11 may be configured with one of the various processors or may be configured with a combination of two or more processors of the same type or of different types (for example, a combination of a plurality of FPGAs or a combination of a CPU and an FPGA).

The system control unit 11 drives the imaging element 5 and the lens device 40 and outputs the subject image captured through the imaging optical system of the lens device 40 as the image signal. By processing the image signal output from the imaging element 5 via the digital signal processing unit 17, captured image data that is data suitable for display on the display device 22 or is data suitable for storage in the storage medium 21 is generated.

An instruction signal from a user is input to the system control unit 11 through the operation unit 14. The operation unit 14 includes a touch panel integrated with a display surface 22b, and various buttons and the like.

The display device 22 comprises the display surface 22b configured with an organic electroluminescence (EL) panel, a liquid crystal panel, or the like, and a display controller 22a that controls display on the display surface 22b.

The memory control unit 15, the digital signal processing unit 17, the external memory control unit 20, and the display controller 22a are connected to each other through a control bus 24 and through a data bus 25 and are controlled in accordance with instructions from the system control unit 11.

FIG. 2 is a schematic plan view showing a schematic configuration of the imaging element 5 shown in FIG. 1. The imaging element 5 comprises an imaging surface 60 on which a plurality of pixel rows 62 consisting of a plurality of pixels 61 arranged in a row direction X are arranged in a column direction Y intersecting (in the example in the drawing, orthogonal to) the row direction X, a drive circuit 63 that drives the pixels 61 arranged on the imaging surface 60, and a signal processing circuit 64 that processes pixel signals (output data of the pixels 61) read out to signal lines from the respective pixels 61 of the pixel rows 62 arranged on the imaging surface 60.

An angle formed by a ray incident on the pixel 61 and an optical axis of the imaging optical system is defined as a light incidence angle. The light incidence angle is larger at a right end portion and a left end portion of the imaging surface 60 and at an upper end portion and a lower end portion of the imaging surface 60 than at a central portion of the imaging surface 60 (in the vicinity of a place intersecting the optical axis of the imaging optical system). In other words, in a case where a position of the pixel 61 at the intersection with the optical axis on the imaging surface 60 is set as a reference position, the light incidence angle of the pixel 61 increases as the position of the pixel 61 is farther from the reference position.

FIG. 3 is a schematic diagram showing a partially enlarged imaging surface 60 of the imaging element 5 shown in FIG. 2. The plurality of pixels 61 disposed on the imaging surface 60 include pixels each corresponding to a plurality (three in the present embodiment) of wavelength ranges. Specifically, the imaging surface 60 is provided with a pixel 61R (blocks with a character “R” in the drawing) corresponding to a wavelength range of red light, a pixel 61G (blocks with characters “GL” and “GH” in the drawing) corresponding to a wavelength range of green light, and a pixel 61B (blocks with a character “B” in the drawing) corresponding to a wavelength range of blue light. The wavelength range of the green light constitutes a first wavelength range.

On the imaging surface 60, a pixel row in which the pixel 61R and the pixel 61G are alternately arranged in the row direction X and a pixel row in which the pixel 61G and the pixel 61B are alternately arranged in the row direction X are alternately arranged in the column direction Y. Each pixel 61 provided on the imaging surface 60 receives light in the corresponding wavelength range and outputs a pixel signal corresponding to the amount of the light.

The pixel 61G includes two types of the pixel, which are a high-sensitivity pixel 61GH and a low-sensitivity pixel 61GL. In the example of FIG. 3, the low-sensitivity pixel 61GL is provided in a part of the pixel row 62 including the pixel 61B and the pixel 61G.

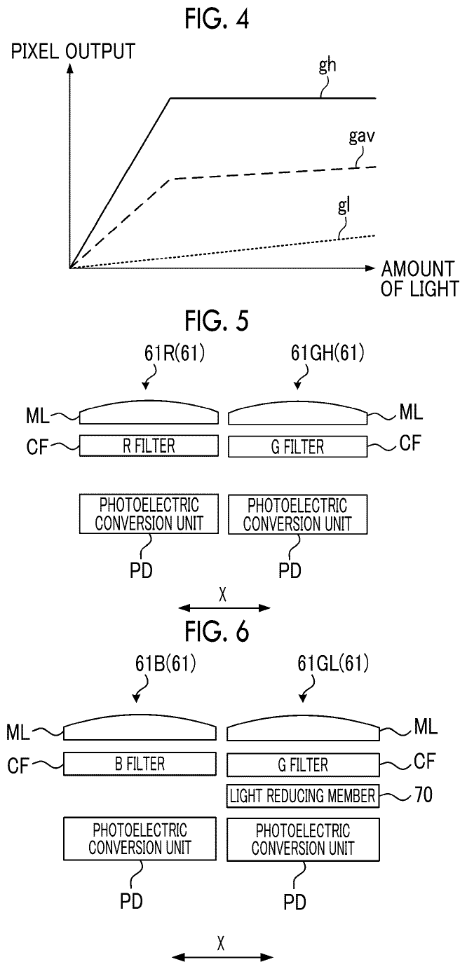

The low-sensitivity pixel 61GL has lower sensitivity than the high-sensitivity pixel 61GH. FIG. 4 is a diagram showing sensitivity characteristics of the high-sensitivity pixel 61GH and the low-sensitivity pixel 61GL. In FIG. 4, a graph gh shows a sensitivity characteristic of the high-sensitivity pixel 61GH, a graph gl shows a sensitivity characteristic of the low-sensitivity pixel 61GL, and a graph gav shows an arithmetic mean of the graph gh and the graph gl. As shown in FIG. 4, even in a case where the same amount of light is incident on the photoelectric conversion units of the low-sensitivity pixel 61GL and the high-sensitivity pixel 61GH, output data of the low-sensitivity pixels 61GL is smaller than output data of the high-sensitivity pixels 61GH.

As described above, in the imaging element 5, for the pixel 61G corresponding to the wavelength range of the green light, which is a wavelength range that contributes most to obtaining a brightness signal, two types of the pixel, which are the high-sensitivity pixel 61GH and the low-sensitivity pixel 61GL, are provided. According to this configuration, for example, by calculating an arithmetic mean of the output data of the high-sensitivity pixel 61GH and the low-sensitivity pixel 61GL located in the vicinity of each other, even in a case of imaging a subject region having a high brightness, it is possible to prevent the pixel output from being saturated by widening the dynamic range as in the graph gav of FIG. 4.

The low-sensitivity pixel 61GL constitutes a first pixel. Each pixel 61 (the pixel 61R, the pixel 61GH, and the pixel 61B) except for the low-sensitivity pixel 61GL among the pixels 61 on the imaging surface 60 constitutes a second pixel.

FIG. 5 is a schematic cross-sectional view of the pixel 61R and the high-sensitivity pixel 61GH in a range A1 shown in FIG. 3. FIG. 6 is a schematic cross-sectional view of the pixel 61B and the low-sensitivity pixel 61GL in a range A2 shown in FIG. 3.

As shown in FIGS. 5 and 6, the pixels 61 provided on the imaging surface 60 include, as common constituent to all the pixels 61, a photoelectric conversion unit PD composed of a photodiode or the like, a microlens ML that condenses light from a subject to the photoelectric conversion unit PD, and a color filter CF that is provided between the photoelectric conversion unit PD and the microlens ML and transmits light in a specific wavelength range. Although not shown, a light shielding film that defines a light-receiving area of the photoelectric conversion unit PD, a light shielding film that shields a signal readout circuit disposed close to the photoelectric conversion unit PD, and the like are provided between the photoelectric conversion unit PD and the color filter CF.

The color filter CF (referred to as an R filter in the drawing) included in the pixel 61R transmits the red light, the color filter CF (referred to as a G filter in the drawing) included in the pixel 61G transmits the green light, and the color filter CF (referred to as a B filter in the drawing) included in the pixel 61B transmits the blue light. In a case where red, green, and blue are spectrally divided by the structure of the photoelectric conversion unit PD itself, the color filter CF can be omitted.

The difference between the low-sensitivity pixel 61GL and the other pixels 61 is the presence or absence of a light reducing member 70. As shown in FIGS. 5 and 6, the low-sensitivity pixel 61GL includes the light reducing member 70 disposed between the color filter CF and the photoelectric conversion unit PD. However, the pixel 61R, the high-sensitivity pixel 61GH, and the pixel 61B do not include the light reducing member 70, respectively. It is preferable that the light reducing member 70 is disposed on a microlens ML side with respect to the light shielding film.

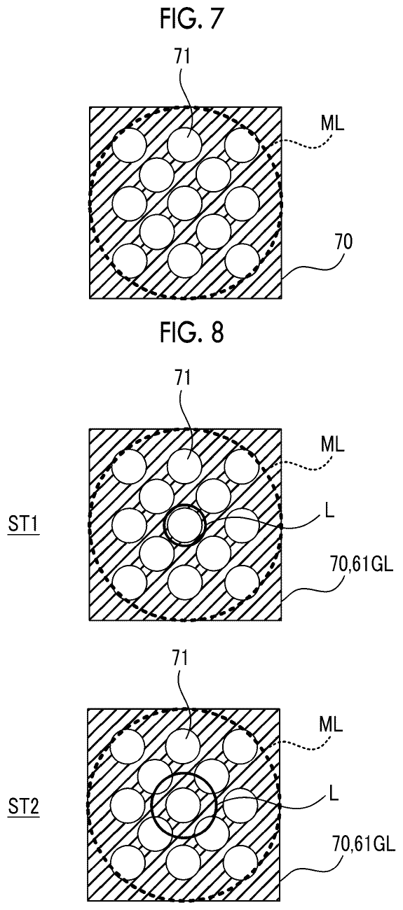

FIG. 7 is a schematic plan view of the light reducing member 70 shown in FIG. 6 as viewed from the microlens ML side. The light reducing member 70 has a plate shape and has a plurality of (13 in the example in the drawing) openings 71 penetrating in a thickness direction thereof. The plurality of openings 71 are arranged in a direction intersecting (specifically, orthogonal to) the optical axis of the imaging optical system. A portion other than the opening 71 in the light reducing member 70 has a light shielding performance, and only light that has passed through the opening 71 and is incident on the microlens ML of the low-sensitivity pixel 61GL reaches the photoelectric conversion unit PD and is converted into a charge.

As described above, the low-sensitivity pixel 61GL is configured to have lower sensitivity than the high-sensitivity pixel 61GH by restricting the amount of light incident on the photoelectric conversion unit PD by the light reducing member 70.

It is required that a sensitivity difference between the high-sensitivity pixel 61GH and the low-sensitivity pixel 61GL (an absolute value of a difference in sensitivity between the two pixels or a sensitivity ratio between the two pixels) is substantially constant regardless of a pixel position on the imaging surface 60. However, in the low-sensitivity pixel 61GL including the light reducing member 70 shown in FIG. 7, the sensitivity difference from the high-sensitivity pixel 61GH may change depending on the state of the imaging optical system. Hereinafter, a case where the sensitivity difference between the high-sensitivity pixel 61GH and the low-sensitivity pixel 61GL is changed depending on the state of the imaging optical system will be described with reference to the drawings.

FIG. 8 is a schematic diagram for describing a change in the sensitivity difference between the high-sensitivity pixel 61GH and the low-sensitivity pixel 61GL depending on an F number (F value). FIG. 8 shows a state in which the ray L is incident on the low-sensitivity pixel 61GL at a position where the image height is close to 0. A state ST1 shown in FIG. 8 shows a state in which the F value is the maximum. A state ST2 shown in FIG. 8 shows a state in which the F value is smaller than the F value in the state ST1.

As shown in the state ST1, in a case where the F value is the maximum, most of the ray L passes through the opening 71 located at the center of the low-sensitivity pixels 61GL and are incident on the photoelectric conversion unit PD. On the other hand, in the high-sensitivity pixel 61GH at the position where the image height is close to 0, since the light reducing member 70 is not provided, all of the ray Lis incident on the photoelectric conversion unit PD.

In the state ST2, the amount of the ray L that can pass through the opening 71 of the low-sensitivity pixel 61GL is decreased as compared with the state ST1. On the other hand, in the high-sensitivity pixel 61GH at the position where the image height is close to 0, all of the ray L is incident on the photoelectric conversion unit PD as in the state ST1. Therefore, in the state ST2, the difference (that is, the sensitivity difference) in the output data between the high-sensitivity pixel 61GH and the low-sensitivity pixel 61GL at the position where the image height is close to 0 is larger compared to the state ST1.

For example, in a case where a ratio of the output data of the low-sensitivity pixel 61GL with respect to the output data of the high-sensitivity pixel 61GH is 90% in the state ST1, the ratio of the output data of the low-sensitivity pixel 61GL with respect to the output data of the high-sensitivity pixel 61GH is 80% in the state ST2.

The size of the ray L shown in FIG. 8 changes not only depending on the F value but also depending on the focus lens position and the zoom lens position. Therefore, for example, even in the state ST1, in a case where the focus lens position or the zoom lens position is changed, the sensitivity difference between the high-sensitivity pixel 61GH and the low-sensitivity pixel 61GL is changed.

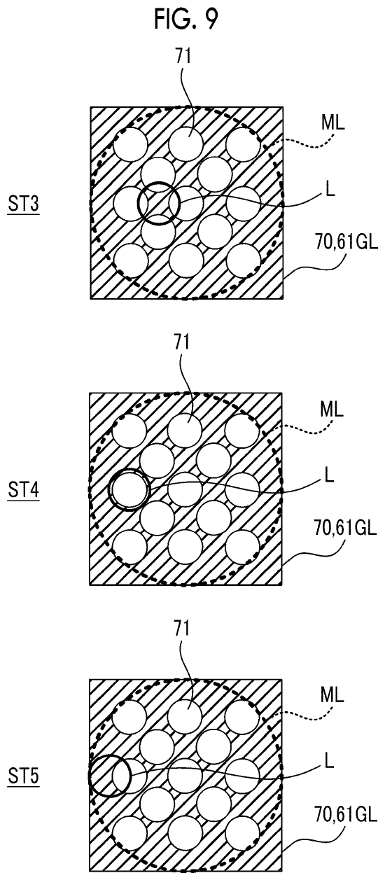

In addition, even in a state in which the F value, the focus lens position, or the zoom lens position is the same, the sensitivity difference between the high-sensitivity pixel 61GH and the low-sensitivity pixel 61GL changes depending on the image height (pixel position). FIG. 9 is a schematic diagram for describing a change in the sensitivity difference between the high-sensitivity pixel 61GH and the low-sensitivity pixel 61GL depending on the image height.

A state ST3 shown in FIG. 9 shows a state in which the ray L is incident on the low-sensitivity pixel 61GL at the position where the image height is close to 0 in a state in which the F value is the maximum. A state ST4 shown in FIG. 9 shows a state in which the ray Lis incident on the low-sensitivity pixel 61GL at the position where the image height is larger compared to the state ST3. A state ST5 shown in FIG. 9 shows a state in which the ray Lis incident on the low-sensitivity pixel 61GL at a position where the image height is larger compared to the state ST4. The F value, the focus lens position, and the zoom lens position in each of the state ST3, the state ST4, and the state ST5 are the same.

As shown in the state ST1 in FIG. 8, in the low-sensitivity pixel 61GL at the position where the image height is close to 0, most of the ray L passes through the opening 71. On the other hand, in the state ST3 shown in FIG. 9, since most of the ray L is blocked by the light reducing member 70, the sensitivity difference between the low-sensitivity pixel 61GL and the high-sensitivity pixel 61GH in the vicinity of the low-sensitivity pixel 61GL is larger compared to the state ST1.

In addition, in the state ST4, similarly to the state ST1, most of the ray L can pass through the opening 71. Therefore, the sensitivity difference between the low-sensitivity pixel 61GL and the high-sensitivity pixel 61GH in the vicinity of the low-sensitivity pixel 61GL is equivalent to the state ST1.

In addition, in the state ST5, since most of the ray L is blocked by the light reducing member 70, the sensitivity difference between the low-sensitivity pixel 61GL and the high-sensitivity pixel 61GH in the vicinity of the low-sensitivity pixel 61GL is larger compared to the state ST1 or the state ST4.

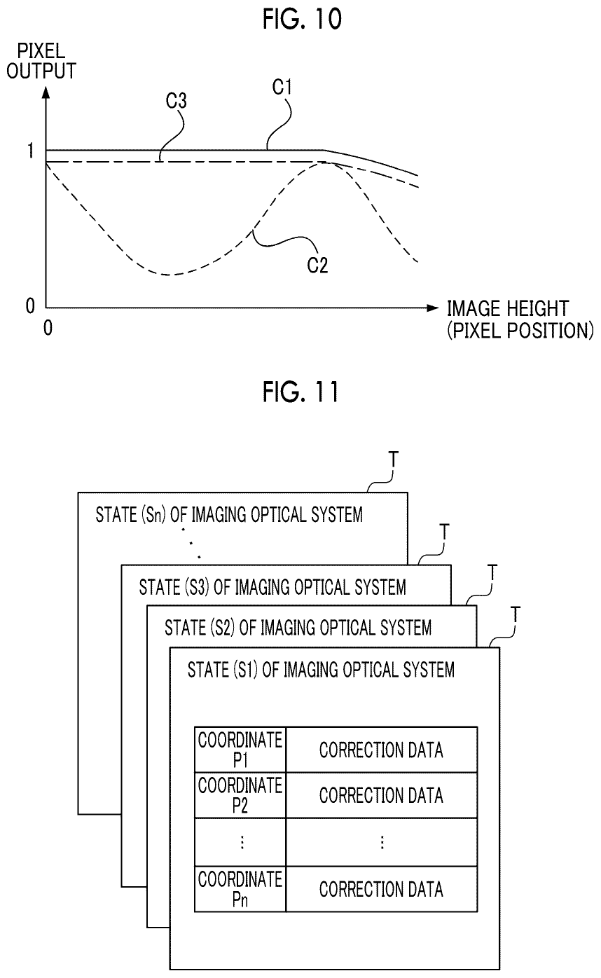

FIG. 10 is a graph showing a change in the output data of the low-sensitivity pixel 61GL and the high-sensitivity pixel 61GH depending on the image height. In FIG. 10, a curve C1 indicates an output of the high-sensitivity pixel 61GH, and a curve C2 indicates an output of the low-sensitivity pixel 61GL.

As in the curve C2, in the low-sensitivity pixel 61GL, the peak value of the output data of the low-sensitivity pixel 61GL is smaller than the peak value of the output data of the high-sensitivity pixel 61GH, and the output data increases or decreases depending on the image height. On the other hand, in the high-sensitivity pixel 61GH, there is almost no fluctuation in the output data depending on the image height, and the output data gradually decreases toward the peripheral edge of the imaging surface 60 in the peripheral portion of the imaging surface 60 where the image height is large. Therefore, the sensitivity difference between the high-sensitivity pixel 61GH and the low-sensitivity pixel 61GL having the same image height increases or decreases in a manner that substantially reflects the shape of the curve C2.

Even in the low-sensitivity pixel 61GL at the same position, the light incidence angle changes in a case where the combination of the F value, the focus lens position, and the zoom lens position changes. Therefore, in the curve C2 shown in FIG. 10, the position of the curve C2 fluctuates up and down or the positions of the peak and the bottom move left and right depending on the combination of the F value, the focus lens position, and the zoom lens position. In addition, in the curve C1, the image height at which the output data begins to decrease is shifted to left and right, or the degree of decrease in the output data changes depending on the combination of the F value, the focus lens position, and the zoom lens position.

In the digital camera 100, the system control unit 11 performs processing of correcting the sensitivity difference with respect to the output data of the low-sensitivity pixel 61GL such that the sensitivity difference between the high-sensitivity pixel 61GH and the low-sensitivity pixel 61GL is substantially constant over the entire imaging surface 60 regardless of the state of the imaging optical system and the position in the imaging surface 60. In the example of FIG. 10, by correcting the output data of the low-sensitivity pixel 61GL indicated by the curve C2 to be a curve C3, the sensitivity difference between the high-sensitivity pixel 61GH and the low-sensitivity pixel 61GL is corrected to the default value at any position on the imaging surface 60. The processing of correcting the curve C2 to the curve C3 can also be referred to as processing of correcting the variation in the output data of the low-sensitivity pixel 61GL in the imaging surface 60.

The correction data used in the processing of correcting the sensitivity difference (output variation of the low-sensitivity pixel 61GL) is generated in a case of manufacturing and is stored in the memory 16. Specifically, the curve C1 and the curve C2 shown in FIG. 10 are measured, and correction data (specifically, a gain for amplifying a signal) for correcting the curve C2 to the curve C3 is obtained for each low-sensitivity pixel 61GL. By associating the correction data for each low-sensitivity pixel 61GL obtained in this manner with information (the combination of the F value, the focus lens position, and the zoom lens position) indicating the state of the imaging optical system in a case where the output shown in FIG. 10 is obtained, the correction table T as shown in FIG. 11 is generated. By performing such processing while changing the state of the imaging optical system, the correction table T is generated for each of all the states (S1 to Sn) that the imaging optical system can take, and the correction tables T are stored in the memory 16.

In a case where the focus lens position of the imaging optical system is fixed, the focus lens position is excluded from the information. In addition, in a case where the imaging optical system has the zoom magnification that cannot changed, the zoom lens position is excluded from the information. In addition, in a case where the F value of the imaging optical system is fixed, the F value is excluded from the information.

In a case where the image signal is acquired from the imaging element 5, the system control unit 11 acquires the information (the combination of the F value, the focus lens position, and the zoom lens position) on the state of the imaging optical system in a case of acquiring the image signal, and reads out the correction table T corresponding to the acquired information from the memory 16. Then, the system control unit 11 corrects the output data of the low-sensitivity pixels 61GL at each position by using the correction data corresponding to the position, in accordance with the read out correction table T.

In the correction table T shown in FIG. 11, the correction data is stored in correspondence with each coordinate of the low-sensitivity pixel 61GL. However, the imaging surface 60 may be divided into groups in a range of a plurality of image heights, and the correction data may be associated with each group.

In a case where the digital camera 100 is a camera in which the lens device 40 (imaging optical system) is interchangeable, it is preferable to generate a correction table group consisting of the correction table T for each state of the imaging optical system shown in FIG. 11 for each type of the lens device 40 (imaging optical system) and store the correction table group in the memory 16. In this case, the system control unit 11 may recognize the type of the lens device 40 mounted on the body part 100A and perform the correction of the sensitivity difference by using the correction table group corresponding to the recognized type.

The relationship between the curve C1 and the curve C2 shown in FIG. 10 also changes depending on the light amount distribution for each wavelength in the green light incident on the low-sensitivity pixel 61GL. Since the refraction state of the microlens ML changes depending on the wavelength, the amount of light incident on the photoelectric conversion unit PD of the low-sensitivity pixel 61GL also changes depending on which wavelength range is included in a larger amount in the green light incident on the low-sensitivity pixel 61GL.

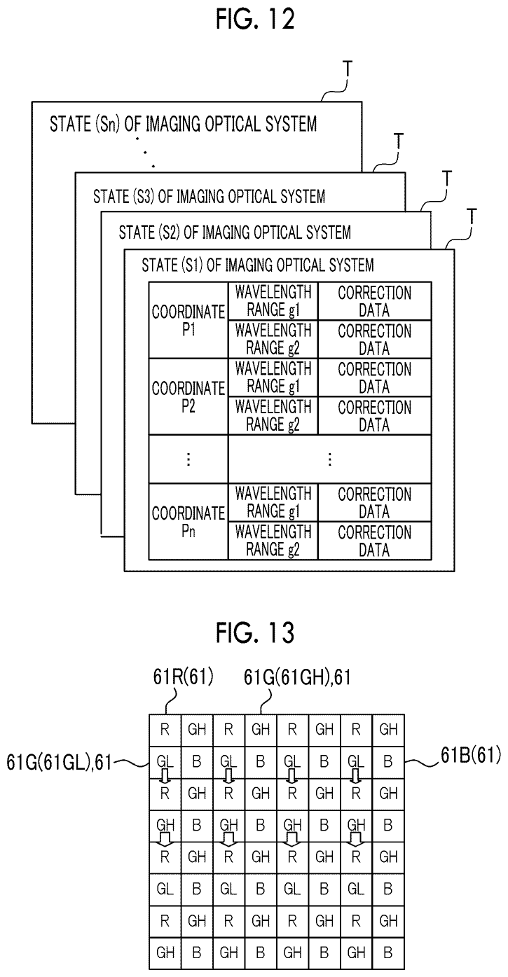

For example, it is preferable to divide the wavelength range of the green light into a plurality of wavelength ranges (for example, two wavelength ranges, which are a wavelength range g1 on the short wavelength side and a wavelength range g2 on the long wavelength side) and to generate the respective pieces of correction data in the correction table T shown in FIG. 11 by dividing into a case where light including a large amount of the wavelength range g1 is incident on the low-sensitivity pixel 61GL and a case where light including a large amount of the wavelength range g2 is incident on the low-sensitivity pixel 61GL, as shown in FIG. 12.

In this case, the system control unit 11 estimates the light amount distribution of the light incident on the low-sensitivity pixel 61GL to be corrected, based on the output data of the pixel 61R and the pixel 61B other than the low-sensitivity pixel 61GL in the vicinity of the low-sensitivity pixel 61GL to be corrected. In a case where it is determined from the estimation result that the light incident on the low-sensitivity pixel 61GL to be corrected includes a relatively large amount of the wavelength range g1, the system control unit 11 corrects the output data of the low-sensitivity pixel 61GL by using the correction data corresponding to the wavelength range g1 among the correction data corresponding to the low-sensitivity pixel 61GL. In this way, it is possible to perform appropriate correction according to the imaging environment.

In the above description, it is assumed that only the pixel 61G among the pixel 61R, the pixel 61G, and the pixel 61B includes two types of the pixel, which are the low-sensitivity pixel and the high-sensitivity pixel. However, one or both of the pixel 61R and the pixel 61B may also include two types of the pixel, which are the low-sensitivity pixel and the high-sensitivity pixel.

The refraction state of light in the microlens ML changes depending on a wavelength of the incident light. Therefore, for example, in a case where one or both of the pixel 61R and the pixel 61B include two types of the pixel, which are the high-sensitivity pixel and the low-sensitivity pixel, it is preferable to generate the correction table group shown in FIG. 11 by dividing into a correction table corresponding to the wavelength range of the green light, a correction table corresponding to the wavelength range of the red light, and a correction table corresponding to the wavelength range of the blue light, and to store the correction table group in the memory 16. The wavelength range of red light and the wavelength range of blue light each constitute a second wavelength range.

In this case, in a case where the low-sensitivity pixel to be corrected is the pixel 61R, the system control unit 11 may acquire a correction table corresponding to the state of the imaging optical system from the correction table group corresponding to the wavelength range of the red light, read out the correction data corresponding to the position of the low-sensitivity pixel to be corrected from the correction table, and correct the output data of the low-sensitivity pixel to be corrected.

Similarly, in a case where the low-sensitivity pixel to be corrected is the pixel 61G, the system control unit 11 may acquire a correction table corresponding to the state of the imaging optical system from the correction table group corresponding to the wavelength range of the green light, read out the correction data corresponding to the position of the low-sensitivity pixel to be corrected from the correction table, and correct the output data of the low-sensitivity pixel to be corrected.

Similarly, in a case where the low-sensitivity pixel to be corrected is the pixel 61B, the system control unit 11 may acquire a correction table corresponding to the state of the imaging optical system from the correction table group corresponding to the wavelength range of the blue light, read out the correction data corresponding to the position of the low-sensitivity pixel to be corrected from the correction table, and correct the output data of the low-sensitivity pixel to be corrected. In this way, the sensitivity difference can be corrected with high accuracy.

In the imaging element 5, the pixel 61 including the light reducing member 70 and the pixel 61 not including the light reducing member 70 are present together. Therefore, the amount of the color mixing component generated by the light incident on the photoelectric conversion unit PD of the pixel 61 adjacent to the pixel 61 in which the light has passed through the color filter CF of the pixel 61 is different between the pixel 61 that is adjacent to the low-sensitivity pixel 61GL and the pixel 61 that is not adjacent to the low-sensitivity pixel 61GL.

Specifically, in the pixel 61 adjacent to the low-sensitivity pixel 61GL, the amount of light incident on the photoelectric conversion unit PD of the pixel 61 from the low-sensitivity pixel 61GL is reduced by the presence of the light reducing member 70 of the low-sensitivity pixel 61GL. Therefore, the amount of the color mixing component from the low-sensitivity pixel 61GL included in the output data of the pixel 61 adjacent to the low-sensitivity pixel 61GL is relatively small. In each pixel 61 adjacent to the pixel 61 other than the low-sensitivity pixel 61GL, since the light reducing member 70 is not included in the adjacent pixel 61, the amount of the color mixing component from the adjacent pixel 61 is relatively large.

For example, as shown in FIG. 13, the pixel 61R includes a pixel 61R adjacent to the low-sensitivity pixel 61GL adjacent to a side close to the center of the imaging surface 60, and a pixel 61R adjacent to the high-sensitivity pixel 61GH adjacent to a side close to the center of the imaging surface 60. In the pixel 61R adjacent to the low-sensitivity pixel 61GL, the amount of the color mixing component from the adjacent low-sensitivity pixel 61GL is small as indicated by the thickness of the white arrow in the drawing. On the other hand, in the pixel 61R adjacent to the high-sensitivity pixel 61GH, the amount of the color mixing component from the adjacent high-sensitivity pixel 61GH is large as indicated by the thickness of the white arrow in the drawing. Therefore, in the example of FIG. 13, it is preferable that the correction data used for the color mixing correction of the output data of the pixel 61R is separately generated for the pixel 61R disposed adjacent to the low-sensitivity pixel 61GL and the pixel 61R disposed adjacent to the high-sensitivity pixel 61GH.

In addition, due to the influence of the light reducing member 70, even in the pixel 61R disposed adjacent to the low-sensitivity pixel 61GL, the amount of light incident from the low-sensitivity pixel 61GL changes depending on the position of the low-sensitivity pixel 61GL and the state of the imaging optical system. Therefore, it is preferable that the correction data used for the color mixing correction of the pixel 61R also changes depending on the position of the adjacent low-sensitivity pixel 61GL and the state of the imaging optical system.

That is, it is preferable that the memory 16 stores, as the correction data used for the color mixing correction of the output data of each pixel 61R, the correction data corresponding to the combination of the position of the low-sensitivity pixel 61GL adjacent to the pixel 61R and the information indicating the state of the imaging optical system. Then, the system control unit 11 can appropriately perform the color mixing correction on all the pixels 61R by performing the color mixing correction of the output data of the pixel 61R using the correction data corresponding to the combination of the position of the low-sensitivity pixel 61GL adjacent to the pixel 61R and the information indicating the state of the imaging optical system.

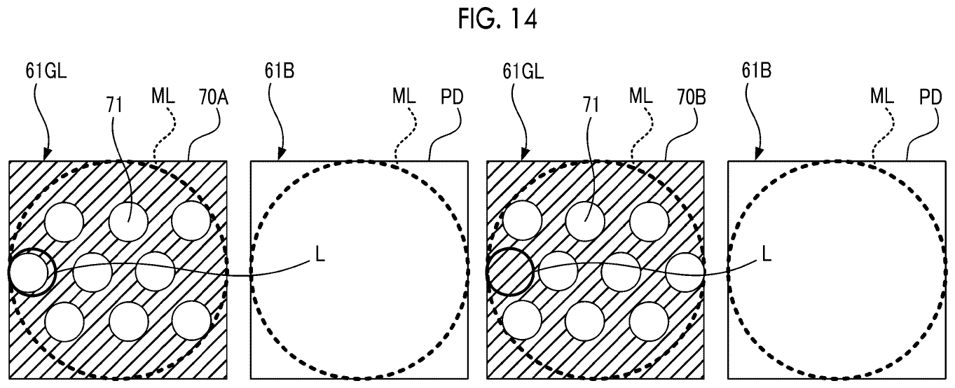

FIG. 14 is a diagram showing a modification example of a configuration of the low-sensitivity pixel 61GL in the imaging element 5, and corresponds to an enlarged plan view of a range A3 in FIG. 3. In the above description, the disposition of the plurality of openings 71 in the light reducing member 70 is the same in all the low-sensitivity pixels 61GL. In the modification example shown in FIG. 14, a plurality of types of the low-sensitivity pixels 61GL in which the disposition of the plurality of openings 71 is different from each other are provided.

In the imaging element 5 of the modification example shown in FIG. 14, two types are provided as the low-sensitivity pixels 61GL, which are a low-sensitivity pixel 61GL in which a light reducing member 70A is disposed instead of the light reducing member 70 and a low-sensitivity pixel 61GL in which a light reducing member 70B is disposed instead of the light reducing member 70. In the imaging element 5, the pair of the two types of low-sensitivity pixels 61GL is discretely disposed on the entire imaging surface 60.

The light reducing member 70A and the light reducing member 70B comprises openings 71 of the same size and the same number, but the disposition of the plurality of openings 71 provided in each of the light reducing member 70A and the light reducing member 70B is different. For example, the plurality of openings 71 of the light reducing member 70A and the plurality of openings 71 of the light reducing member 70B are in a line-symmetrical relationship with each other with a straight line extending in the column direction Y as a line of symmetry. The light reducing member 70A and the light reducing member 70B each may have a plurality of openings 71 that are disposed randomly. Alternatively, the light reducing member 70A and the light reducing member 70B may have the same disposition pattern of the plurality of openings 71 and may be configured such that two disposition patterns are misaligned in at least one of the row direction X or the column direction Y.

As shown in FIG. 14, in a case where the imaging element 5 is provided with a plurality of types of low-sensitivity pixels 61GL, the system control unit 11 corrects the output data of each of the plurality of low-sensitivity pixels 61GL based on the output data of different types of the plurality of low-sensitivity pixels 61GL.

Even in a case where the low-sensitivity pixel 61GL having the light reducing member 70A and the low-sensitivity pixel 61GL having the light reducing member 70B are disposed close to each other, the amount of light incident on each photoelectric conversion unit PD of the two types of low-sensitivity pixels 61GL is different from each other since the disposition of the openings 71 is different.

For example, in a case where the ray L is incident at a position shown in FIG. 14, a large amount of the ray L is incident on the photoelectric conversion unit PD of the low-sensitivity pixel 61GL including the light reducing member 70A, but almost no ray L is incident on the photoelectric conversion unit PD of the low-sensitivity pixel 61GL including the light reducing member 70B.

Even in such a case, the system control unit 11 calculates the arithmetic mean of the output data of the low-sensitivity pixel 61GL including the light reducing member 70A and the output data of the low-sensitivity pixel 61GL including the light reducing member 70B, and performs correction of using the calculated value as the output data of each low-sensitivity pixel 61GL. Accordingly, it is possible to make the curve C2 closer to the curve C3 by leveling the variation in the output of the low-sensitivity pixels 61GL depending on the pixel position as shown in FIG. 10 without performing the correction of the sensitivity difference described above. In addition, by performing the correction of the sensitivity difference described above after the correction of the leveling, the gain to be multiplied by the output data of the low-sensitivity pixel 61GL can be reduced, and noise can be suppressed.

Next, a configuration of a smartphone which is another embodiment of the imaging apparatus according to the present invention will be described.

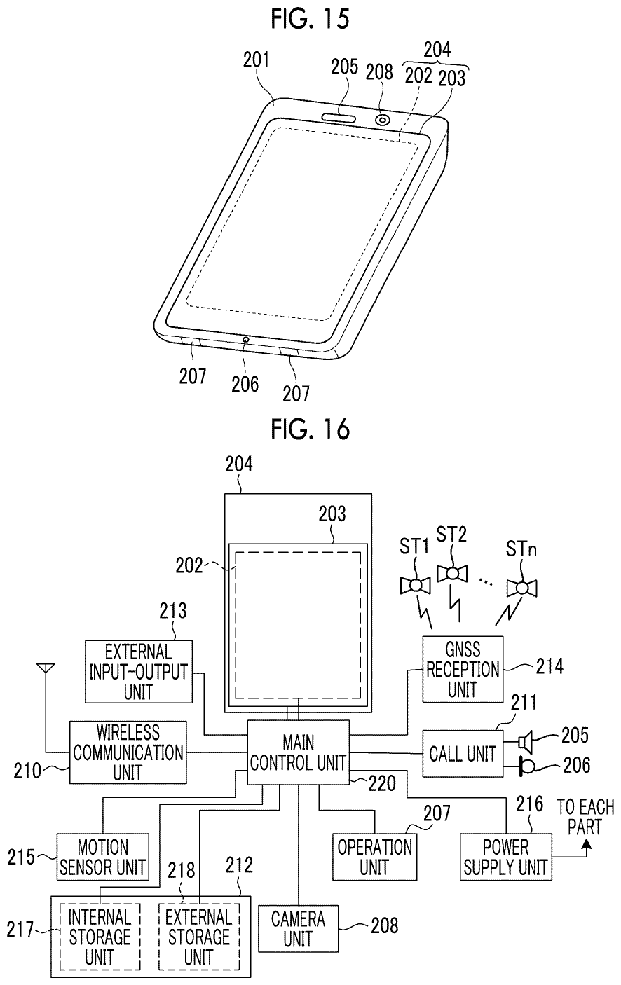

FIG. 15 is a diagram showing an exterior of the smartphone 200. The smartphone 200 shown in FIG. 15 includes a housing 201 having a flat plate shape and comprises a display and input unit 204 in which a display panel 202 as a display unit and an operation panel 203 as an input unit are integrated on one surface of the housing 201.

In addition, the housing 201 comprises a speaker 205, a microphone 206, an operation unit 207, and a camera unit 208. The configuration of the housing 201 is not limited thereto and, for example, a configuration in which the display unit and the input unit are independently disposed can be employed, or a configuration having a folded structure or a sliding mechanism can be employed.

FIG. 16 is a block diagram showing a configuration of the smartphone 200 shown in FIG. 15.

As shown in FIG. 16, the smartphone comprises, as main constituents, a wireless communication unit 210, the display and input unit 204, a call unit 211, the operation unit 207, the camera unit 208, a storage unit 212, an external input-output unit 213, a global navigation satellite system (GNSS) reception unit 214, a motion sensor unit 215, a power supply unit 216, and a main control unit 220.

In addition, the smartphone 200 comprises, as a main function, a wireless communication function of performing mobile wireless communication via a base station apparatus BS (not shown) and a mobile communication network NW (not shown).

The wireless communication unit 210 performs wireless communication with the base station apparatus BS accommodated in the mobile communication network NW in accordance with instructions from the main control unit 220. By using the wireless communication, transmission and reception of various file data such as audio data and image data, electronic mail data, or the like and reception of web data, streaming data, or the like are performed.

The display and input unit 204 is a so-called touch panel that visually delivers information to the user by displaying images (still images and video images), text information, or the like and that detects a user operation with respect to the displayed information under control of the main control unit 220. The display and input unit 204 comprises the display panel 202 and the operation panel 203.

The display panel 202 uses a liquid crystal display (LCD), an organic electroluminescence display (OELD), or the like as a display device.

The operation panel 203 is a device that is placed such that an image displayed on a display surface of the display panel 202 can be visually recognized, and that detects one or a plurality of coordinates operated with a finger of the user or with a stylus. In a case where the device is operated with the finger of the user or with the stylus, a detection signal generated by the operation is output to the main control unit 220. Next, the main control unit 220 detects an operation position (coordinates) on the display panel 202 based on the received detection signal.

As shown in FIG. 16, although the display panel 202 and the operation panel 203 of the smartphone 200 shown as an embodiment of the imaging apparatus according to the present invention are integrated to constitute the display and input unit 204, the operation panel 203 is disposed to completely cover the display panel 202.

In a case where such disposition is employed, the operation panel 203 may comprise a function of detecting the user operation even in a region outside the display panel 202. In other words, the operation panel 203 may comprise a detection region (hereinafter, referred to as a display region) for an overlapping portion overlapping with the display panel 202 and a detection region (hereinafter, referred to as a non-display region) for an outer edge portion, other than the overlapping portion, that does not overlap with the display panel 202.

A size of the display region and a size of the display panel 202 may completely match, but both sizes do not need to match. In addition, the operation panel 203 may comprise two sensitive regions of the outer edge portion and an inner portion other than the outer edge portion. Furthermore, a width of the outer edge portion is appropriately designed depending on a size and the like of the housing 201.

Furthermore, examples of a position detection method employed in the operation panel 203 include a matrix switch method, a resistive membrane system, a surface acoustic wave method, an infrared method, an electromagnetic induction method, and a capacitance method, and any method can be employed.

The call unit 211 comprises the speaker 205 or the microphone 206, and converts voice of the user input through the microphone 206 into audio data processable in the main control unit 220 and outputs the audio data to the main control unit 220, or decodes audio data received by the wireless communication unit 210 or by the external input-output unit 213 and outputs the decoded audio data from the speaker 205.

In addition, as shown in FIG. 15, for example, the speaker 205 can be mounted on the same surface as a surface on which the display and input unit 204 is provided, and the microphone 206 can be mounted on a side surface of the housing 201.

The operation unit 207 is a hardware key that uses a key switch or the like, and receives instructions from the user. For example, as shown in FIG. 15, the operation unit 207 is a push button-type switch that is mounted on the side surface of the housing 201 of the smartphone 200, and is turned on by being pressed with the finger or the like and is set to an OFF state by a restoring force of a spring or the like in a case where the finger is released.

The storage unit 212 stores a control program and control data of the main control unit 220, application software, address data in which a name, a telephone number, or the like of a communication counterpart is associated, transmitted and received electronic mail data, web data downloaded by web browsing, and downloaded contents data, and temporarily stores streaming data or the like. In addition, the storage unit 212 is configured with an internal storage unit 217 incorporated in the smartphone and with an external storage unit 218 that has a slot for an attachable and detachable external memory.

Each of the internal storage unit 217 and the external storage unit 218 constituting the storage unit 212 is implemented using a storage medium such as a memory (for example, a MicroSD (registered trademark) memory) of a flash memory type, a hard disk type, a multimedia card micro type, or a card type, a random access memory (RAM), or a read only memory (ROM).

The external input-output unit 213 serves as an interface with all external apparatuses connected to the smartphone 200 and is directly or indirectly connected to other external apparatuses by communication or the like (for example, a universal serial bus (USB), IEEE1394, Bluetooth (registered trademark), radio frequency identification (RFID), infrared communication (Infrared Data Association (IrDA) (registered trademark)), Ultra Wideband (UWB) (registered trademark), or ZigBee (registered trademark)) or through a network (for example, Ethernet (registered trademark) or a wireless local area network (LAN)).

For example, the external apparatuses connected to the smartphone 200 include a wired/wireless headset, a wired/wireless external charger, a wired/wireless data port, a memory card and a subscriber identity module (SIM)/user identity module (UIM) card connected via a card socket, an external audio and video apparatus connected via an audio and video input/output (I/O) terminal, an external audio and video apparatus connected in a wireless manner, a smartphone connected in a wired/wireless manner, a personal computer connected in a wired/wireless manner, and an earphone.

The external input-output unit 213 can deliver data transferred from the external apparatuses to each constituent in the smartphone 200 or transfer data in the smartphone 200 to the external apparatuses.

The GNSS reception unit 214 receives GNSS signals transmitted from GNSS satellites ST1 to STn, executes positioning computation processing based on the received plurality of GNSS signals, and detects a position consisting of a latitude, a longitude, and an altitude of the smartphone 200 in accordance with instructions from the main control unit 220. In a case where positional information can be acquired from the wireless communication unit 210 or from the external input-output unit 213 (for example, a wireless LAN), the GNSS reception unit 214 can detect the position using the positional information.

The motion sensor unit 215 comprises, for example, a three-axis acceleration sensor and detects a physical motion of the smartphone 200 in accordance with instructions from the main control unit 220. By detecting the physical motion of the smartphone 200, a movement direction or acceleration of the smartphone 200 is detected. The detection result is output to the main control unit 220.

The power supply unit 216 supplies power stored in a battery (not shown) to each unit of the smartphone 200 in accordance with instructions from the main control unit 220.

The main control unit 220 comprises a microprocessor, operates in accordance with the control program and with the control data stored in the storage unit 212, and manages and controls each unit of the smartphone 200. The microprocessor of the main control unit 220 has the same function as the system control unit 11. In addition, the main control unit 220 comprises a mobile communication control function of controlling each unit of a communication system and an application processing function in order to perform voice communication or data communication through the wireless communication unit 210.

The application processing function is implemented by operating the main control unit 220 in accordance with the application software stored in the storage unit 212. For example, the application processing function is an infrared communication function of performing data communication with counter equipment by controlling the external input-output unit 213, an electronic mail function of transmitting and receiving electronic mails, or a web browsing function of viewing a web page.

In addition, the main control unit 220 comprises an image processing function such as displaying an image on the display and input unit 204 based on image data (data of a still image or of a video image) such as reception data or downloaded streaming data.

The image processing function refers to a function of causing the main control unit 220 to decode the image data, perform image processing on the decoding result, and display the image on the display and input unit 204.

Furthermore, the main control unit 220 executes a display control of the display panel 202 and an operation detection control of detecting user operations performed through the operation unit 207 and through the operation panel 203.

By executing the display control, the main control unit 220 displays an icon for starting the application software or a software key such as a scroll bar or displays a window for creating an electronic mail.

The scroll bar refers to a software key for receiving an instruction to move a display portion of an image, such as a large image that does not fit in the display region of the display panel 202.

In addition, by executing the operation detection control, the main control unit 220 detects the user operation performed through the operation unit 207, receives an operation with respect to the icon and an input of a text string in an input field of the window through the operation panel 203, or receives a request for scrolling the display image made through the scroll bar.

Furthermore, by executing the operation detection control, the main control unit 220 comprises a touch panel control function of determining whether the operation position on the operation panel 203 is in the overlapping portion (display region) overlapping with the display panel 202 or is in the outer edge portion (non-display region), other than the overlapping portion, not overlapping with the display panel 202 and of controlling the sensitive region of the operation panel 203 or a display position of the software key.

In addition, the main control unit 220 can detect a gesture operation with respect to the operation panel 203 and execute a function set in advance in accordance with the detected gesture operation.

The gesture operation is not a simple touch operation in the related art and means an operation of drawing a path with the finger or the like, designating a plurality of positions at the same time, or as a combination thereof, drawing a path from at least one of the plurality of positions.

The camera unit 208 includes the lens device 40, the imaging element 5, and the digital signal processing unit 17 shown in FIG. 1.

Captured image data generated by the camera unit 208 can be stored in the storage unit 212 or output through the external input-output unit 213 or through the wireless communication unit 210.

In the smartphone 200 shown in FIG. 16, the camera unit 208 is mounted on the same surface as the display and input unit 204. However, a mount position of the camera unit 208 is not limited thereto. The camera unit 208 may be mounted on a rear surface of the display and input unit 204.

In addition, the camera unit 208 can be used for various functions of the smartphone 200. For example, an image acquired by the camera unit 208 can be displayed on the display panel 202, or the image of the camera unit 208 can be used as one of operation inputs of the operation panel 203.

In addition, in a case where the GNSS reception unit 214 detects the position, the position can be detected by referring to the image from the camera unit 208. Furthermore, by referring to the image from the camera unit 208, it is possible to determine an optical axis direction of the camera unit 208 of the smartphone 200 or to determine the current use environment without using the three-axis acceleration sensor or by using the three-axis acceleration sensor in combination. Of course, the image from the camera unit 208 can also be used in the application software.

In addition, image data of a still image or of a video image to which the positional information acquired by the GNSS reception unit 214, voice information (may be text information acquired by performing voice to text conversion via the main control unit or the like) acquired by the microphone 206, posture information acquired by the motion sensor unit 215, or the like is added can be stored in the storage unit 212 or be output through the external input-output unit 213 or through the wireless communication unit 210.

Although various embodiments have been described above, it goes without saying that the present invention is not limited to these examples. It is apparent that those skilled in the art may perceive various modification examples or correction examples within the scope disclosed in the claims, and those examples are also understood as falling within the technical scope of the present invention. In addition, each of constituents in the embodiments may be combined in any manner without departing from the gist of the invention.

The present application is based on Japanese Patent Application (JP2023-013450) filed on Jan. 31, 2023, the content of which is incorporated in the present application by reference.

### EXPLANATION OF REFERENCES

1: imaging lens
2: stop
4: lens control unit
5: imaging element
8: lens drive unit
9: stop drive unit
11: system control unit
14, 207: operation unit
15: memory control unit
16: memory
17: digital signal processing unit
20: external memory control unit
21: storage medium
22a: display controller
22b: display surface
22: display device
24: control bus
25: data bus
40: lens device
60: imaging surface
61, 61R, 61G, 61B: pixel
61GL: low-sensitivity pixel
61GH: high-sensitivity pixel
62: pixel row
63: drive circuit
64: signal processing circuit
A1, A2, A3: range
gh, gl, gav: graph
PD: photoelectric conversion unit
CF: color filter
ML: microlens
70, 70A, 70B: light reducing member
71: opening
L: ray
C1, C2, C3: curve
T: correction table
100A: body part
100: digital camera
200: smartphone
201: housing
202: display panel
203: operation panel
204: display and input unit
205: speaker
206: microphone
208: camera unit
210: wireless communication unit
211: call unit
212: storage unit
213: external input-output unit
214: GNSS reception unit
215: motion sensor unit
216: power supply unit
217: internal storage unit
218: external storage unit
220: main control unit

What is claimed is:

1. An imaging apparatus comprising:
an imaging element that images a subject through an imaging optical system,
wherein the imaging element includes a plurality of pixels corresponding respectively to a plurality of wavelength ranges,
the imaging element includes a first pixel in which a light reducing member having a plurality of openings is disposed and a second pixel in which the light reducing member is not provided, and
the first pixel corresponds to a first wavelength range among the plurality of wavelength ranges.

2. The imaging apparatus according to claim 1,
wherein the second pixel comprises a pixel corresponding to the first wavelength range.

3. The imaging apparatus according to claim 2,
wherein the first wavelength range is a wavelength range that contributes most to obtaining a brightness signal.

4. The imaging apparatus according to claim 3,
wherein the first pixel comprises a plurality of pixels, the second pixel comprises a plurality of pixels, the plurality of pixels included in the second pixel comprises pixels respectively corresponding to each wavelength range other than the first wavelength range among the plurality of wavelength ranges, and all of the plurality of pixels included in the first pixel correspond to the first wavelength range.

5. The imaging apparatus according to claim 1, further comprising:
a processor,
wherein the processor is configured to:
perform processing, on output data of the first pixel, of correcting a sensitivity difference between the first pixel and the second pixel based on a position of the first pixel and information indicating a state of the imaging optical system.

6. The imaging apparatus according to claim 1, further comprising:
a processor,
wherein the processor is configured to:
perform processing, on output data of the first pixel, of correcting a variation in the output data of the first pixel in an imaging surface based on a position of the first pixel and information indicating a state of the imaging optical system.

7. The imaging apparatus according to claim 5,
wherein the information includes at least one of an F number, a focus lens position, or a zoom lens position.

8. The imaging apparatus according to claim 5, further comprising:
a memory,
wherein correction data to be used in the processing is stored in the memory for each combination of the position of the first pixel and the information indicating the state of the imaging optical system.

9. The imaging apparatus according to claim 8,
wherein the correction data is stored in the memory for each type of the imaging optical system.

10. The imaging apparatus according to claim 5,
wherein the processor is configured to:
estimate light amount distribution for each wavelength of light incident on the first pixel based on output data of the second pixel; and
perform the processing on the output data of the first pixel based on the light amount distribution, the position of the first pixel, and the information.

11. The imaging apparatus according to claim 10,
wherein the information includes at least one of an F number, a focus lens position, or a zoom lens position.

12. The imaging apparatus according to claim 10, further comprising:
a memory,
wherein correction data to be used in the processing is stored in the memory for each combination of the light amount distribution, the position of the first pixel, and the information indicating the state of the imaging optical system.

13. The imaging apparatus according to claim 12,
wherein the correction data is stored in the memory for each type of the imaging optical system.

14. The imaging apparatus according to claim 1, further comprising:
a processor,
wherein the imaging element has the first pixel corresponding to a second wavelength range among the plurality of wavelength ranges, and
the processor is configured to:
perform processing, on output data of the first pixel, of correcting a sensitivity difference between the first pixel and the second pixel based on a position of the first pixel, information indicating a state of the imaging optical system, and a wavelength range corresponding to the first pixel.

15. The imaging apparatus according to claim 1, further comprising:
a processor,
wherein the imaging element has the first pixel corresponding to a second wavelength range among the plurality of wavelength ranges, and
the processor is configured to:
perform processing, on output data of the first pixel, of correcting a variation in the output data of the first pixel in an imaging surface based on a position of the first pixel, information indicating a state of the imaging optical system, and a wavelength range corresponding to the first pixel.

16. The imaging apparatus according to claim 1,
wherein the first pixel includes a plurality of types of pixels in which dispositions of the plurality of openings are different from each other.

17. The imaging apparatus according to claim 16, further comprising:
a processor,
wherein the processor is configured to:
correct output data of each of the plurality of types of pixels based on output data of the plurality of types of pixels.

18. The imaging apparatus according to claim 1, further comprising:
a processor,
wherein the processor is configured to:
perform color mixing correction on output data of the second pixel disposed adjacent to the first pixel based on a position of the first pixel and information indicating a state of the imaging optical system.

19. The imaging apparatus according to claim 18,
wherein the information includes at least one of an F number, a focus lens position, or a zoom lens position.

20. An imaging element that images a subject through an imaging optical system, the imaging element comprising:
a plurality of pixels corresponding respectively to a plurality of wavelength ranges,
wherein the plurality of pixels includes a first pixel in which a light reducing member having a plurality of openings is disposed and a second pixel in which the light reducing member is not provided, and
the first pixel corresponds to a first wavelength range among the plurality of wavelength ranges.
